(19) United States
(12) Patent Application Publication
(10) Pub. No.: US 2013/0320540 A1
(43) Pub. Date: Dec. 5, 2013

(54) SEMICONDUCTOR DEVICE AND METHOD FOR MANUFACTURING THE SAME

(71) Applicants: Yu Shan CHIU, New Taipei City (TW); Wen Ping Liang, New Taipei City (TW)

(72) Inventors: Yu Shan CHIU, New Taipei City (TW); Wen Ping Liang, New Taipei City (TW)

(73) Assignee: Nanya Technology Corporation, Tao-Yuan Hsien (TW)

(21) Appl. No.: 13/488,208

(22) Filed: Jun. 4, 2012

(51) Int. Cl. H01L 23/48; H01L 21/768

(52) U.S. Cl. 257/751; 438/653; 257/E23.011; 257/E21.586

(57) ABSTRACT

A semiconductor device includes a substrate, a conductive material, and a material layer. The substrate includes a through hole. The conductive material fills the through hole. The material layer is formed in the conductive material, wherein an electrical resistance of the conductive material is lower than an electrical resistance of the material layer.

### BACKGROUND OF THE INVENTION

1. Technical Field

The present invention relates to a semiconductor device and a method for manufacturing the same, and more particularly relates to a semiconductor device including through silicon vias and a method for manufacturing the same.

2. Background

For decades, continuous improvements in transistor technology have resulted in smaller and better-performing chips. New materials with higher dielectric constants, along with metal gate electrodes, decrease leakage and boot drive current. Strained silicon technology causes transistors to switch faster. New transistor structures such as double or tri-gate transistors further increase device switching speed while reducing leakage.

In addition to improving transistors, interconnect performance has also been improved by several vertical connect strategies. One of the most promising vertical connect strategies involves through silicon vias (TSVs), which promise the highest vertical interconnect density. TSVs are formed through a silicon wafer to provide short electrical connections between the opposite sides of the silicon wafer. Generally, TSVs are formed by depositing metal into deep through-holes. An electroplating process is the most widely used method of fabrication.

Normally, TSVs are large and deep. Consequently, complete filling with a metal by an electroplating process is time-consuming.

### SUMMARY

According to one embodiment of the present invention, a semiconductor device comprises a substrate, a conductive material, and a material layer. The substrate comprises a through hole. The conductive material fills the through hole. The material layer is formed in the conductive material. An electrical resistance of the conductive material is lower than an electrical resistance of the material layer.

According to another embodiment of the present invention, a semiconductor device comprises a substrate, a seed layer, a material layer, and a conductive material. The substrate comprises a through hole, which is defined by a side wall. The seed layer is formed on the side wall of the substrate. The material layer partially covers the seed layer. The conductive material fills the through hole.

According to one embodiment of the present invention, a method for manufacturing a semiconductor device comprises forming a hole in a substrate, forming a seed layer in the hole, forming a material layer covering an upper portion of the seed layer, filling a conductive material having an electrical resistance lower than that of the material layer in a lower portion of the hole by electroplating, and filling an unfilled portion of the hole with the conductive material by bottom-up electroplating.

The foregoing has outlined rather broadly the features and technical advantages of the present invention in order that the detailed description of the invention that follows may be better understood. Additional features and advantages of the invention will be described hereinafter, and form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives and advantages of the present invention are illustrated with the following description and upon reference to the accompanying drawings in which:

FIG. 1 schematically illustrates a semiconductor device according to one embodiment; and

FIGS. 2 to 7 are cross-sectional views schematically depicting the steps of a method for manufacturing a semiconductor device according to one embodiment.

### DETAILED DESCRIPTION

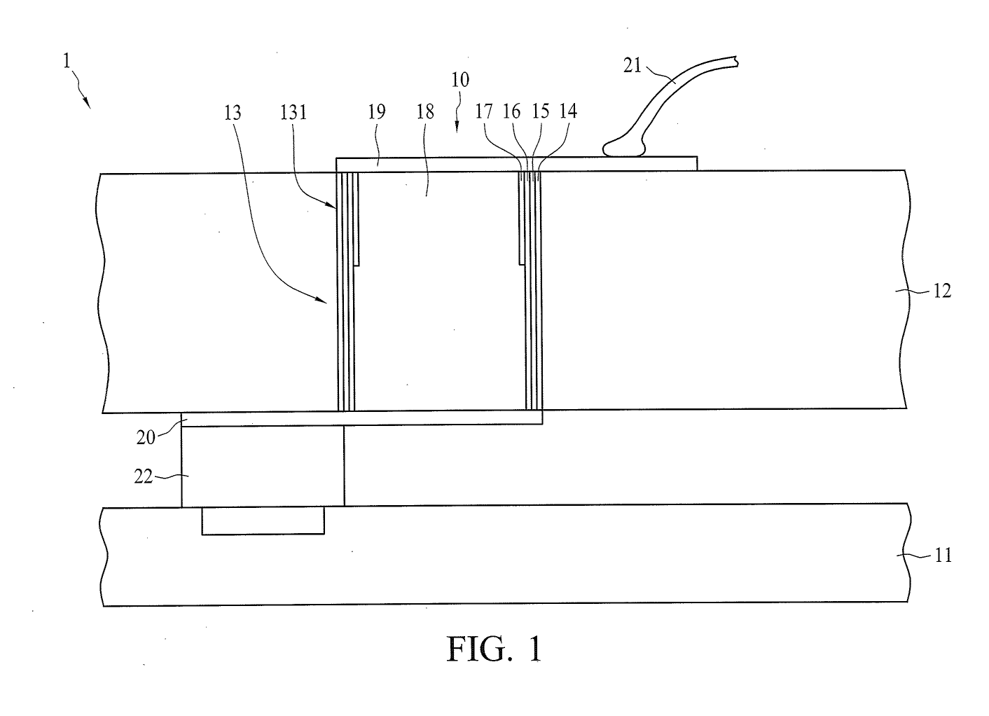

FIG. 1 schematically illustrates a semiconductor device 1 according to one embodiment of the present invention. As shown in FIG. 1, the semiconductor device 1 may comprise a substrate 12, which includes a through hole 13. The through hole 13 may be defined by a side wall 131. A plurality of layers formed on the side wall 131 include an insulating layer 14, a barrier layer 15, and a seed layer 16. Conductive material 18 is applied to fill the through hole 13. Moreover, a material layer 17 is formed between the seed layer 16 and the conductive material 18, and partially covers the seed layer 16. The material layer 17 has an electrical resistance higher than that of the conductive material 18. In some embodiments, the seed layer 16 is formed by a material similar to the conductive material 18. As such, the material layer 17 is embedded in the conductive material 18.

In some embodiments, the substrate 12 may comprise silicon. In some embodiments, the substrate 12 may typically be a silicon substrate. In some embodiments, the substrate 12 may be made of any semiconductor material.

The insulating layer 14 is formed on the side wall 131 defining the through hole 13. The insulating layer 14 electrically isolates the TSV 10 from the substrate 12. The insulating layer 14 may comprise a material of silicon dioxide (SiO₂), silicon nitride (Si₃N₄), silicon oxynitride (SiON), tantalum pentoxide (Ta₂O₅), and aluminum oxide (Al₂O₃). The insulating layer 14 may alternatively comprise polyimide, benzocyclobutene (BCB), polybenzoxazoles (PBO), or other suitable dielectric material.

The barrier layer 15 is formed on the insulating layer 14. The barrier layer 15 is used to avoid the migration of conductive material 18 into the substrate 12. The barrier layer 15 may also improve the adhesion between the conductive material 18 and the insulating layer 14. In some embodiments, the barrier layer 15 may include a material of titanium nitride (TiN), tantalum nitride (TaN), tantalum (Ta), titanium (Ti), or the like. In some embodiments, the barrier layer 15 comprises tungsten (W), tungsten nitride (WN), chromium (Cr), niobium (Nb), cobalt (Co), nickel (Ni), platinum (Pt), ruthenium (Ru), palladium (Pd), gold (Au), or the like. In some embodiments, the barrier layer 15 may comprise cobalt phosphide (CoP), cobalt tungsten phosphide (CoWP), nickel phosphide (NiP), nickel tungsten boride (NiWP), or the like.

The seed layer 16 is deposited on the barrier layer 15. The seed layer 16 can be made of a conductor. In some embodiments, the seed layer 16 comprises copper. In some embodiments, the seed layer 16 comprises copper-based alloy. The seed layer 16 may be deposited by PVD or CVD. Alternative technologies, such as CVD of metals such as W and Co and electrografting of Cu, can also be applied to form the seed layer 16.

The material layer 17 is formed on the seed layer 16, partially covering the seed layer 16. The material layer 17 may be formed in the upper portion of the through hole 13; in other words, the material layer 17 covers the upper portion of the seed layer 16. The material layer 17 has an electrical resistance higher than that of the conductive material 18 such that the lower portion of the through hole 13 can be sufficiently filled with conductive material 18 without the occurrence of unacceptable defects while a suitable deposition process is applied. The material layer 17 may comprise a metal or non-metal layer. The material layer 17 may also be made of dielectric material. In some embodiments, the material layer 17 comprises tantalum, tantalum nitride, titanium, titanium nitride, tantalum carbon nitride, ruthenium, manganese, or a combination thereof.

In some embodiments, the conductive material 18 can be filled into the through hole 13 by an electrochemical plating (ECP) process. The conductive material 18 can be a conductor. In some embodiments, the conductive material 18 comprises copper. In some embodiments, the conductive material 18 comprises a material of tungsten, aluminum, gold, silver, or the like.

Referring again to FIG. 1, pads 19 and 20 can be respectively formed on the upper and lower surfaces of the substrate 12, coupling to the TSV 10. Solder balls 22 can be formed on the pad 20 and used to electrically connect another device or substrate 11. A wire 21 can be bonded to the pad 19 for electrical connection. Alternatively, the substrate 12 may comprise a circuit, which may couple to an external device or substrate through the TSV 10.

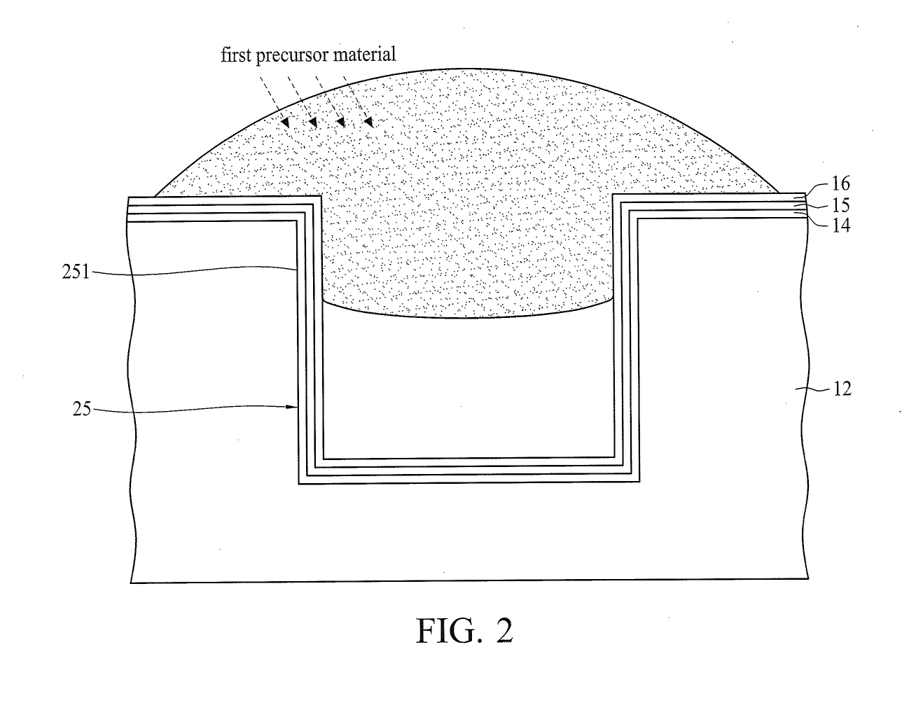

FIGS. 2 to 7 are cross-sectional views schematically depicting the steps of a method for manufacturing a semiconductor device 1 according to one embodiment of the present invention. As illustrated in FIG. 2, a TSV hole 25 is formed in a substrate 12. The TSV hole 25 is generally not formed through the substrate 12. The TSV hole 25 may be formed by an etch process, and can be etched to a certain depth or until an etch-stop layer is reached. The etch process may be a plasma etch process, a wet etch process, a laser drilling process, or any suitable etch process. Alternatively, the etch process may be a deep reactive ion etching process. The TSV hole 25 may have a vertical or sloped side wall 251.

Referring to FIGS. 1 and 2, an insulating material is deposited on the side wall 251 of the TSV hole 25 to form an insulating layer 14. The insulating material may include a material of silicon dioxide (SiO₂), silicon nitride (Si₃N₄), silicon oxynitride (SiON), tantalum pentoxide (Ta₂O₅), aluminum oxide (Al₂O₃), polyimide, benzocyclobutene (BCB), polybenzoxazoles (PBO), or other suitable dielectric material. The insulating material may be deposited using PVD (physical vapor deposition), CVD (chemical vapor deposition), or thermal oxidation.

A material that can prevent the migration of conductive material 18 into the substrate 12 and/or improve the adhesion between the conductive material 18 and the insulating layer 14 is deposited on the insulating layer 14 to form the barrier layer 15. In some embodiments, the material may comprise TiN, TaN, Ta, Ti, W, WN, Cr, Nb, Co, Ni, Pt, Ru, Pd, or Au. In some embodiments, the material may comprise CoP, CoWP, NiP, or NiWP. The material can be deposited by PVD, CVD, ALD (atomic layer deposition), or an electroplating process.

A conductive material is deposited on the barrier layer 15 to obtain a seed layer 16. In some embodiments, the conductive material comprises copper. In some embodiments, the conductive material comprises copper-based alloy. In some embodiments, the conductive material may comprise W or Co. The conductive material may be deposited by PVD, CVD, or an electrografting process.

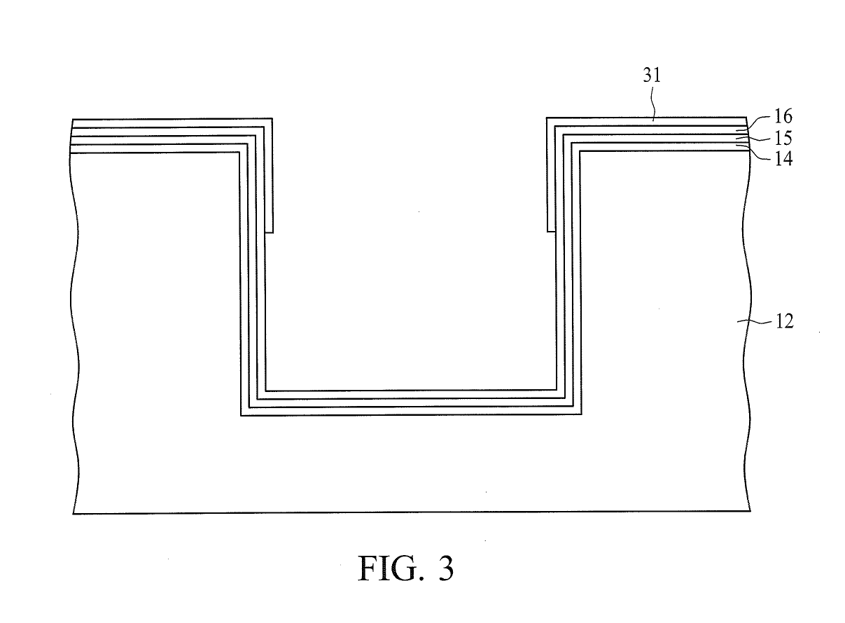

Referring to FIGS. 1 and 2, the material layer 17 is preferably formed by a deposition method, in which reactant species are introduced sequentially in a repetitive mode, separated by purging with an inert gas. As shown in FIG. 2, a first precursor material is introduced. The reaction pressure or the flow rate of the gaseous first precursor material is properly controlled such that the first precursor material covers the seed layer 16 on the upper surface of the substrate 12 and enters an upper portion of the TSV hole 25. As a result, molecules of first precursor material forming a first precursor material layer 31 as shown in FIG. 3 are absorbed by the seed layer 16 on the upper surface of the substrate 12 and in the upper portion of the TSV hole 25. Once the first precursor material layer 31 is formed, the first precursor material is drawn away from the substrate 12, and the substrate 12 is then purged with an inert gas.

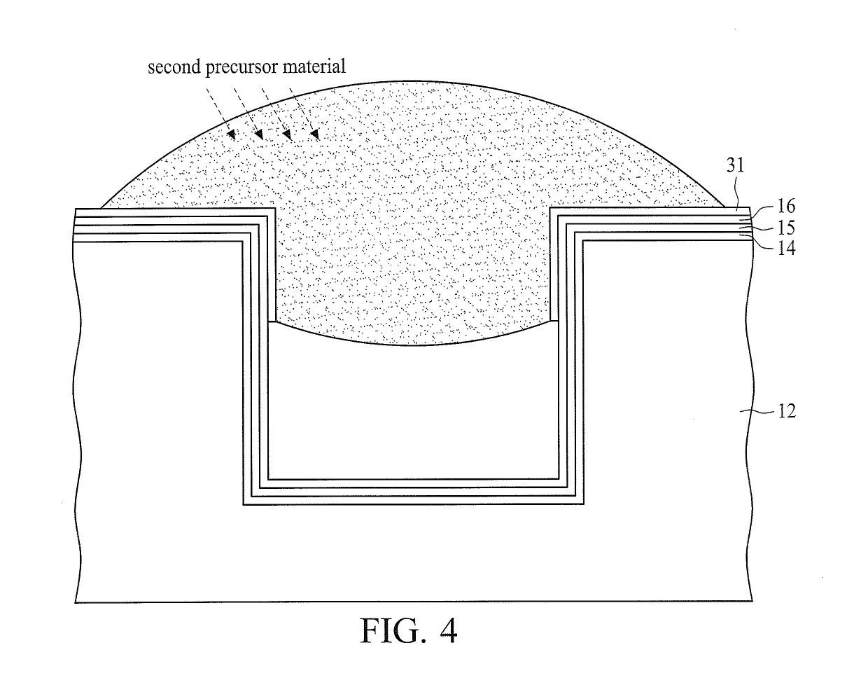

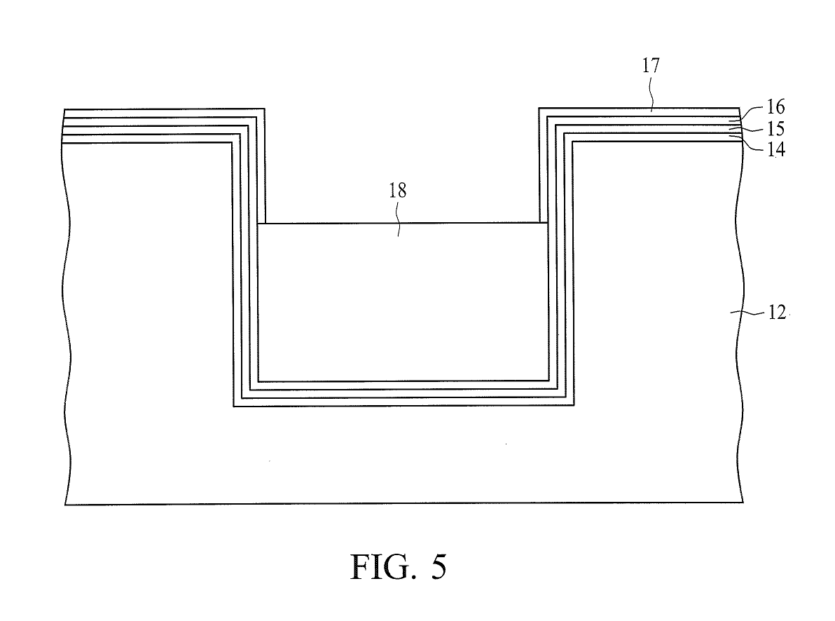

Referring to FIG. 4, a second precursor material is introduced to react with the chemisorbed first precursor material on the seed layer 16 to form the material layer 17, as shown in FIG. 5, covering the seed layer 16 on the upper surface of the substrate 12 and in the upper portion of the TSV hole 25. After the material layer 17 is formed, the second precursor material is drawn away from the substrate, and a purge gas is introduced. The first and second precursor materials can be introduced sequentially in a repetitive mode, separated by purging with an inert gas such that a desired thickness of the material layer 17 is obtained.

Suitable first and second precursor materials can be applied to form the material layer 17 having an electrical resistance higher than that of the conductive material 18. The material layer 17 may comprise a metal or non-metal layer. In some embodiments, the material layer 17 comprises tantalum, tantalum nitride, titanium, titanium nitride, tantalum carbon nitride, ruthenium, manganese, or a combination thereof. Alternatively, in some embodiments, the material layer 17 may also be made of dielectric material.

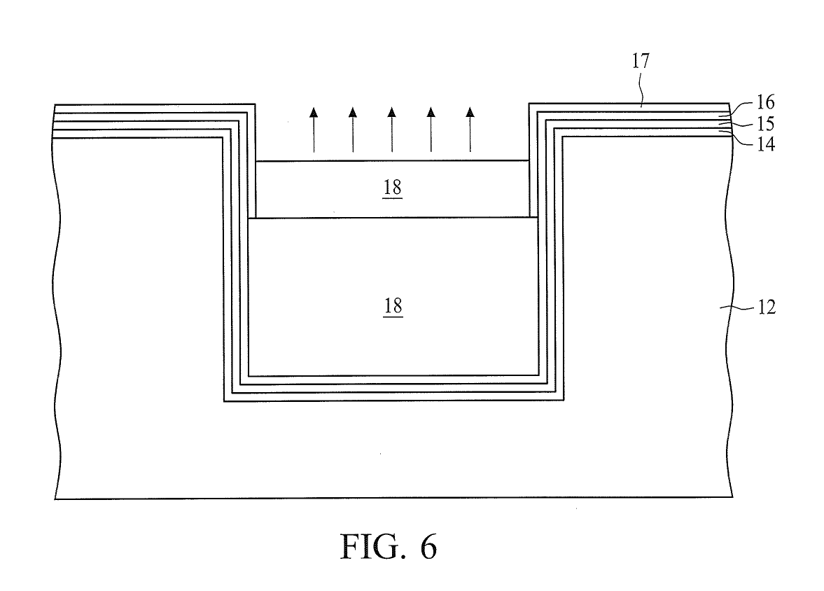

Referring to FIGS. 1, 5 and 6, the lower portion of the TSV hole 25 is first filled as shown in FIG. 5. The lower portion of the TSV hole 25 can be filled with conductive material 18 such as Cu, Cu-based alloy, W and Co by an electroplating process providing a faster plating rate than that of the bottom-up electroplating process. In some embodiments, the electroplating process is a conformal electroplating process. The material layer 17 can maintain a diffusion path, extending to the lower portion of the TSV hole 25 from the outside of the TSV hole 25, for metal ions in electrolyte. The material layer 17 on the upper surface of the substrate 12 may reduce the thickness of the overburden. Next, a bottom-up electroplating, which produces better electroplating quality, is subsequently performed to fill the unfilled portion of the TSV hole 25 as shown in FIG. 6.

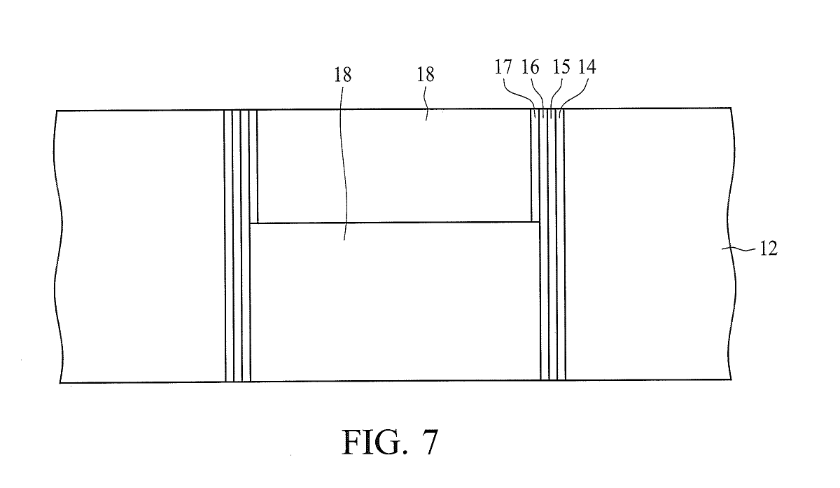

Referring to FIG. 7, the portions including the insulating layer 14, the barrier layer 15, and the material layer 17 above the upper surface of the substrate 12 are removed by, for example, a chemical mechanical polishing process. The substrate 12 is then thinned to expose the bottom of the TSV 10.

Embodiments demonstrate a new approach to form TSVs. Compared to the conformal electroplating process, the new approach can provide better quality of TSV, avoiding the generation of TSVs with voids or seams. Compared to the bottom-up electroplating method, the new approach can fill TSV holes more quickly.

In the following description, numerous details, such as specific materials, dimensions, and processes, are set forth in order to provide a thorough understanding of the present invention. However, one skilled in the art will realize that the invention may be practiced without these particular details. In other instances, well-known semiconductor equipment and processes have not been described in particular detail so as to avoid obscuring the present invention.

Although the present invention and its advantages have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A semiconductor device comprising:
a substrate comprising a through hole;
a conductive material filling the through hole; and
a material layer formed in the conductive material, wherein an electrical resistance of the conductive material is lower than an electrical resistance of the material layer.

2. The semiconductor device of claim 1, wherein the material layer is in an upper portion of the through hole.

3. The semiconductor device of claim 1, wherein the material layer comprises a metal layer or a non-metal layer.

4. The semiconductor device of claim 1, wherein the material layer comprises tantalum, tantalum nitride, titanium, titanium nitride, tantalum carbon nitride, ruthenium, manganese, or a combination thereof.

5. The semiconductor device of claim 1, wherein the conductive material comprise copper.

6. The semiconductor device of claim 1, further comprising a barrier layer formed on a side wall of the through hole.

7. The semiconductor device of claim 6, further comprising an insulating layer formed between the barrier layer and the side wall of the through hole.

8. A semiconductor device comprising:
a substrate comprising a through hole defined by a side wall;
a seed layer formed on the side wall of the substrate;
a material layer partially covering the seed layer; and
a conductive material filling the through hole.

9. The semiconductor device of claim 8, wherein the material layer covers an upper portion of the seed layer.

10. The semiconductor device of claim 8, wherein the material layer comprises a metal layer or a non-metal layer.

11. The semiconductor device of claim 8, wherein the material layer comprises tantalum, tantalum nitride, titanium, titanium nitride, tantalum carbon nitride, ruthenium, manganese, or a combination thereof.

12. The semiconductor device of claim 8, wherein the conductive material comprises copper.

13. The semiconductor device of claim 8, further comprising a barrier layer formed on the side wall of the through hole.

14. The semiconductor device of claim 13, further comprising an insulating layer formed between the barrier layer and the side wall of the through hole.

15. A method for manufacturing a semiconductor device, comprising the steps of
forming a hole in a substrate;
forming a seed layer in the hole;
forming a material layer covering an upper portion of the seed layer;
filling a conductive material having an electrical resistance lower than that of the material layer in a lower portion of the hole by electroplating; and
filling an unfilled portion of the hole with the conductive material by bottom-up electroplating.

16. The method of claim 15, wherein the material layer comprises a metal layer or a non-metal layer.

17. The method of claim 15, wherein the material layer comprises tantalum, tantalum nitride, titanium, titanium nitride, tantalum carbon nitride, ruthenium, manganese, or a combination thereof.

18. The method of claim 15, wherein the conductive material comprises copper.

19. The method of claim 15, wherein the seed layer comprises copper.
